(19) United States
(12) Patent Application Publication
(10) Pub. No.: US 2015/0061001 A1
(43) Pub. Date: Mar. 5, 2015

(54) SEMICONDUCTOR DEVICE

(71) Applicant: RENESAS ELECTRONICS CORPORATION, Kawasaki-shi (JP)

(72) Inventor: Masahiro IKEDA, Kanagawa (JP)

(73) Assignee: RENESAS ELECTRONICS CORPORATION, Kawasaki-shi (JP)

(21) Appl. No.: 14/457,578

(22) Filed: Aug. 12, 2014

(30) Foreign Application Priority Data
Sep. 2, 2013 (JP) 2013-181311

(51) Int. Cl. H01L 29/423; H01L 29/78; H01L 27/088

(52) U.S. Cl. CPC H01L 29/4236; H01L 27/088; H01L 29/7827
USPC 257/331

(57) ABSTRACT

A semiconductor device which includes a microfabricated transistor with buried gate electrodes. In the semiconductor device, a gate electrode is formed over a substrate, extending in the direction parallel to the first side of a device formation region. The gate electrode lies across the device formation region. A plurality of buried gate electrodes are buried in the device formation region of the substrate and in a plan view, the gate electrode partially overlap them. The buried gate electrodes extend obliquely to the first side of the device formation region and are parallel to each other. In each buried gate electrode, the first end opposite to the first side and the second end opposite to the second end of the device formation region are both parallel to the first side.

### CROSS-REFERENCE TO RELATED APPLICATIONS

The disclosure of Japanese Patent Application No. 2013-181311 filed on Sep. 2, 2013 including the specification, drawings and abstract is incorporated herein by reference in its entirety.

### BACKGROUND

The present invention relates to semiconductor devices and more particularly to technology for semiconductor devices with buried gate electrodes.

In recent years, studies have been carried out on techniques of burying transistor gate electrodes in a substrate in order to get a wider transistor channel region.

For example, Japanese Unexamined Patent Application Publication No. 2013-33799 describes that a gate electrode buried in a trench has a varying width in the channel length direction. Specifically the width of the buried gate electrode is the largest in its center and a portion thereof nearer to a source (or drain) has a smaller width.

Also, Japanese Unexamined Patent Application Publication 2007-35957 describes that an n-type transistor and a p-type transistor each have a buried gate electrode and the buried gate electrode of the n-type transistor is located obliquely to a gate electrode.

### SUMMARY

In recent years, there has been a demand for microfabricated semiconductor devices. However, in the case of transistors with buried gate electrodes, since the buried gate electrodes must have a certain degree of width (length in the channel length direction), it is difficult to apply a microfabrication technique. The above and further objects and novel features of the invention will more fully appear from the following detailed description in this specification and the accompanying drawings.

According to one aspect of the invention, there is provided a semiconductor device which includes a substrate, a device separation film, a plurality of buried gate electrodes, a source region, and a drain region. The substrate has a device formation region. The device formation region is rectangular and has a first side, a second side, a third side, and a fourth side. The second side is opposite to the first side and the third and fourth sides are the two other sides. The device separation film is formed in the substrate in a way to surround the device formation region. The buried gate electrodes are buried in the device formation region of the substrate. The buried gate electrodes extend obliquely to the first side and are parallel to each other. The source region and drain region are formed in the device formation region of the substrate and spaced from each other in the direction parallel to the third side. The source region and drain region are opposite to each other with the buried gate electrodes between them. In the buried gate electrodes, the first ends opposite to the first side and the second ends opposite to the second side are all parallel to the first side.

According to the present invention, it is possible to provide a microfabricated transistor with buried gate electrodes.

### BRIEF DESCRIPTION OF THE DRAWINGS

FIG. 1 is a plan view showing the structure of a semiconductor device according to a first embodiment of the present invention;

FIG. 2 is a sectional view taken along the line A-A′ of FIG. 1;

FIG. 3 is a sectional view taken along the line B-B′ of FIG. 1;

FIGS. 4A and 4B illustrate the method of manufacturing a semiconductor device; and

FIG. 5 is a plan view showing the structure of a semiconductor device according to a second embodiment of the present invention.

### DETAILED DESCRIPTION

Next, the preferred embodiments of the present invention will be described referring to the accompanying drawings. In all the drawings, the same elements are designated by the same reference signs and a repeated description of the same elements will be omitted as appropriate.

In the embodiments described below, the word “parallel” does not always mean “geometrically parallel” but it may mean “almost parallel, or somewhat inclined” (for example, inclined at an angle of 10 degrees or less).

### First Embodiment

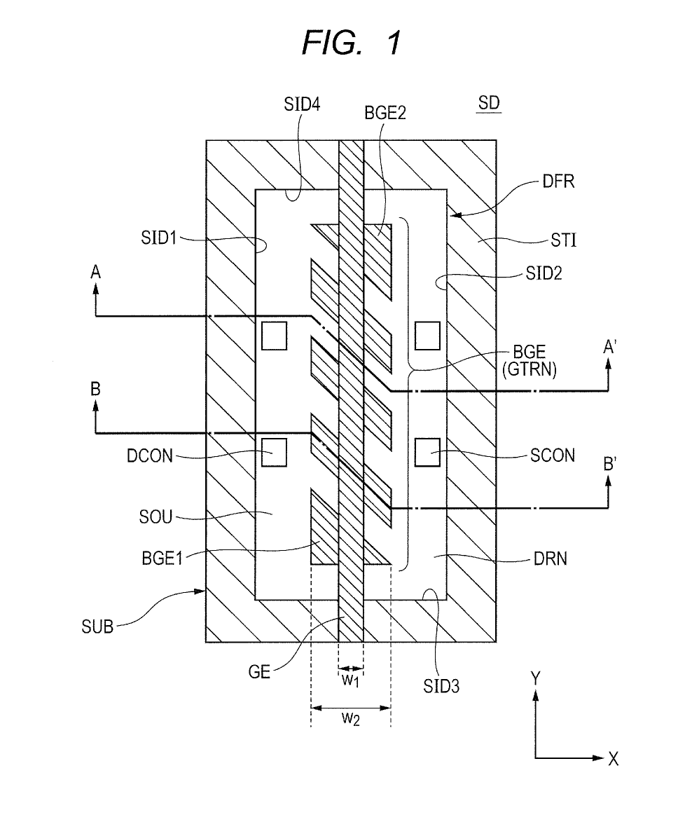

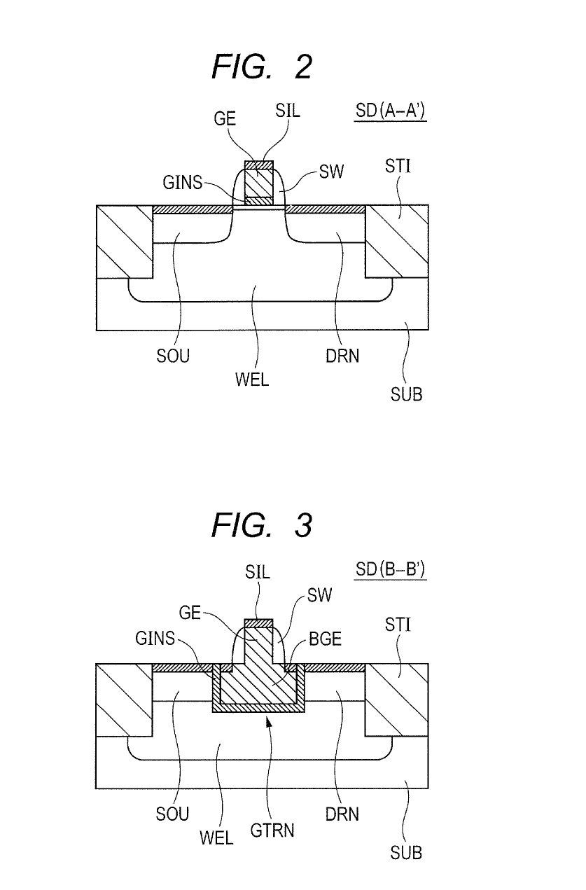

FIG. 1 is a plan view showing the structure of a semiconductor device SD according to the first embodiment. FIG. 2 is a sectional view taken along the line A-A′ of FIG. 1 and FIG. 3 is a sectional view taken along the line B-B′ of FIG. 1. In FIG. 1, a gate insulating film GINS, silicide SIL and sidewalls SW are omitted.

The semiconductor device SD according to this embodiment includes a substrate SUB, a device separation film STI, a plurality of buried gate electrodes BGE, a source region SOU, and a drain region DRN. The substrate SUB has a device formation region DFR. The device formation region DFR is rectangular and has a first side SID1, a second side SID2, a third side SID3, and a fourth side SID4. The second side SID2 is opposite to the first side SID1 and the third side SID3 and fourth side SID4 are the two other sides. The device separation film STI is formed in the substrate SUB in a way to surround the device formation region DFR. The buried gate electrodes BGE are buried in the device formation region DFR of the substrate SUB. The buried gate electrodes BGE extend obliquely to the first side of the device formation region DFR and are parallel to each other.

The source region SOU and drain region DRN are formed in the device formation region DFR of the substrate SUB and spaced from each other in the direction parallel to the third side SID3. The source region SOU and drain region DRN are opposite to each other with the buried gate electrodes BGE between them. In each buried gate electrode BGE, the first end opposite to the first side SID1 and the second end opposite to the second side SID2 are both parallel to the first side SID1. A detailed explanation is given below.

First, the semiconductor device SD will be described referring to FIG. 1. The substrate SUB is a semiconductor substrate such as a silicon substrate. If the substrate SUB is a silicon substrate, the front surface of the substrate is, for example, a (100) surface. The substrate SUB has a device formation region DFR. The device formation region DFR is separated from other regions by the device separation film STI. The device separation region STI is an insulating film such as a silicon oxide film and buried in the substrate SUB. The trench in which the device separation film STI is buried is either deeper than the trench in which a buried gate electrode BGE is buried (gate trench GTRN) or as deep as the gate trench GTRN. In the latter case, the trench in which the device separation film STI is buried is formed in the same process in which the gate trench GTRN is formed.

A trench type transistor is formed in the device formation region DFR. This transistor includes a gate insulating film GINS, a gate electrode GE, buried gate electrodes BGE, a source region SOU, and a drain region DRN.

The source region SOU and drain region DRN are located in the device formation region DFR of the substrate SUB. The source region SOU and drain region DRN are formed by implanting impurities into the substrate SUB. The source region SOU and drain region DRN are, for example, n-type impurity regions; however, instead they may be p-type impurity regions.

The gate electrode GE and buried gate electrodes BGE are formed between the source region SOU and drain region DRN. In other words, the source region SOU and drain region DRN are separated from each other by the regions of the substrate SUB where the gate electrode GE overlaps, and the buried gate electrodes BGE. The gate electrode GE lies over the substrate SUB and the buried gate electrodes BGE are buried in the trenches made in the substrate SUB. The gate electrode GE and buried gate electrodes BGE are integrated together. The gate electrode GE and buried gate electrodes BGE are made of, for example, polysilicon; however, instead they may be made of another conductive material.

The gate electrode GE extends parallel to the first side of the device formation region DFR. For example, if 40-nm generation microfabrication technology is employed, width w₁ of the gate electrode GE is not less than 40 nm and not more than 60 nm. Since the gate electrode GE also serves as wiring, it extends beyond the device formation region DFR.

The buried gate electrodes BGE extend obliquely to the first side SID1. Therefore, in a plan view, the sides of each buried gate electrode BGE which are opposite to the third side SID3 and fourth side SID4 extend obliquely to the first side SID1 except a first buried gate electrode BGE1's side opposite to the third side SID3 and a second buried gate electrode BGE2's side opposite the fourth side SID4 which will be described later. If the substrate SUB is a silicon substrate and its front surface is a (100) surface, it is preferable that the buried gate electrodes BGE extend at an angle of 45 degrees to the first side SID1. If 40-nm generation microfabrication technology is employed, width w₂ of each buried gate electrode BGE in the direction parallel to the third side SID3 is not less than 40 nm and not more than 80 nm. The widths w₁ and w₂ may be out of the above respective ranges. It is desirable that the value of width w₁ be nearly the minimum for the employed microfabrication technology and the value of w₂ be in the range from a value almost equal to the value of w₁ to twice as much as the value of w₁.

The end of each buried gate electrode BGE opposite to the first side SID1 and the side facing the second side SID2 are both parallel to the first side SID1, namely parallel to the gate electrode GE. Therefore, in a plan view, the buried gate electrodes BGE are parallelograms except the first buried gate electrode BGE1 located nearest to the third side SID3 and the second buried gate electrode BGE2 located nearest to the fourth side SID4.

On the other hand, the first buried gate electrode BGE1's side opposite to the third side SID3 is parallel to the third side SID3 and the second buried gate electrode BGE2's side opposite to the fourth side SID4 is parallel to the fourth side SID4. Therefore, in a plan view, the first buried gate electrode BGE1 and the second buried gate electrode BGE2 are right-angled triangles. The first buried gate electrode BGE1 and the second buried gate electrode BGE2 are both located away from the device separation film STI. The reason for this is that if the first buried gate electrode BGE1 and the second buried gate electrode BGE2 should overlap the device separation film STI, variation in the amount of overlap in the overlapping portions could cause variation in the transistor characteristics.

The gate insulating film GINS is formed between the gate electrode GE and the substrate SUB and between each buried gate electrode BGE and the substrate SUB. The gate insulating film GINS is formed, for example, by thermal oxidation of the substrate SUB. Alternatively, the gate insulating film GINS may be formed by a deposition technique.

The source region SOU is coupled to a source contact SCON and the drain region DRN is coupled to a drain contact DCON. The source contact SCON and drain contact DCON are buried in an interlayer insulating film (not shown) made over the substrate SUB and the device separation film STI.

Next, referring to FIGS. 2 and 3, the structure of the semiconductor device SD in its depth direction will be described. As shown in FIG. 2, a gate insulating film GINS is formed between the substrate and the portion of the gate electrode GE which does not overlap a buried gate electrode BGE. Also silicide SIL lies over the gate electrode GE and over the source region SOU and the drain region DRN. The silicide SIL is, for example, Ni silicide; however, it may be another kind of metal silicide such as Co silicide or Ti silicide. Sidewalls SW are formed on the lateral sides of the gate electrode GE.

As shown in FIG. 3, a gate insulating film GINS is also formed between each gate electrode BGE and the substrate SUB.

A well WEL is formed in the device formation region DFR of the substrate SUB. The source region SOU, drain region DRN and gate trench GTRN are formed in the well WEL.

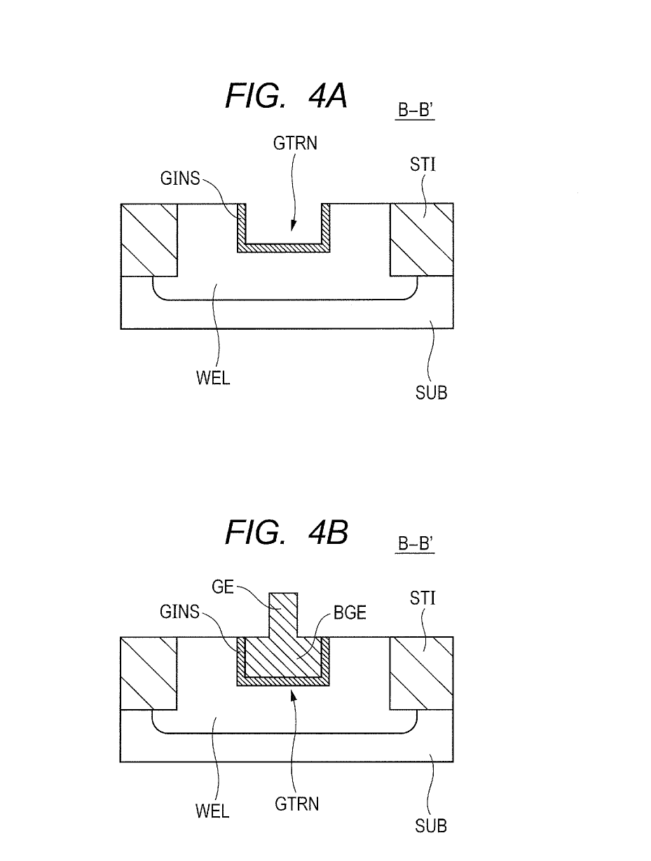

Next, the method of manufacturing the semiconductor device SD will be described referring to FIG. 4. As shown in FIG. 4A, a trench is made in the substrate SUB and a device separation film STI is buried in the trench. Then, a mask pattern (not shown) is formed over the substrate SUB. The opening of the mask pattern has the same pattern as a buried gate electrode BGE. Then, the substrate SUB is etched using the mask pattern as a mask. A gate trench GTRN is thus made in the substrate SUB.

Next, a well WEL is formed in the substrate SUB and impurities for threshold adjustment are implanted into the substrate SUB.

Next, the inner wall and bottom of the gate trench GTRN and the front surface of the substrate SUB are thermally oxidized. A gate insulating film GINS is thus formed. An oxide film is also formed on the surface of the area of the substrate SUB over which the device separation film STI is not formed, though it is not shown in FIG. 4A.

Next, as shown in FIG. 4B, a conductive film (for example, polysilicon film) to form a gate electrode GE and buried gate electrodes BGE is made in the trench GTRN and over the substrate SUB and the device separation film STI. Then, a mask pattern is formed over the conductive film and the conductive film is etched using the mask pattern as a mask. The gate electrode GE and buried gate electrode BGE are thus formed.

After that, sidewalls SW are formed on the lateral sides of the gate electrode GE. Then, impurities are implanted into the substrate SUB using the gate electrode GE, sidewalls SW, and device separation film STI as a mask. Thus a source region SOU and a drain region DRN are formed. Then a metal film is formed over the source region SOU, drain region DRN, and gate electrode GE and the metal film is thermally treated. Silicide SIL is thus formed. After that, an interlayer insulating film, a source contact SCON, and a drain contact DCON are formed.

Alternatively the gate trench GTRN may be formed simultaneously with the formation of a trench in which the device separation film STI is buried. If that is the case, in the step of burying the device separation film STI in the trench, insulator is buried in the gate trench GTRN as well. Therefore, the insulator in the gate trench GTRN must be removed before the formation of the gate insulating film GINS.

Alternatively, the gate electrode GE may be formed in another step after the formation of the buried gate electrodes BGE.

As explained so far, according to this embodiment, the buried gate electrodes BGE extend obliquely to the first side of the device formation region DFR. This means that the buried gate electrodes BGE can be lengthened without the need for an increase in the size of the device formation region DFR. Furthermore, in each buried gate electrode BGE, the first end opposite to the first side SID1 and the second end opposite to the second side SID2 are both parallel to the first side SID1. Therefore, unlike the case that the planar shape of the buried gate electrodes BGE is rectangular, the required distance from each end of the buried gate electrode BGE to the device separation film STI can be provided without the need for an increase in the size of the device formation region DFR so that the source contact SCON and drain contact DCON can be formed. Therefore, for a transistor with buried gate electrodes BGE, microfabrication can be performed in the channel length direction (X direction in FIG. 1).

In the first buried gate electrode BGE1, located nearest to the third side SID3 of the device formation region DFR, among the buried gate electrodes BGE, the side opposite to the third side SID3 is parallel to the third side SID3. In addition, in the second buried gate electrode BGE2, located nearest to the fourth side SID4 of the device formation region DFR, the side opposite to the fourth side SID3 is parallel to the fourth side SID4. Therefore, for a transistor with buried gate electrodes BGE, microfabrication can be performed in the channel width direction (Y direction in FIG. 1).

### Second Embodiment

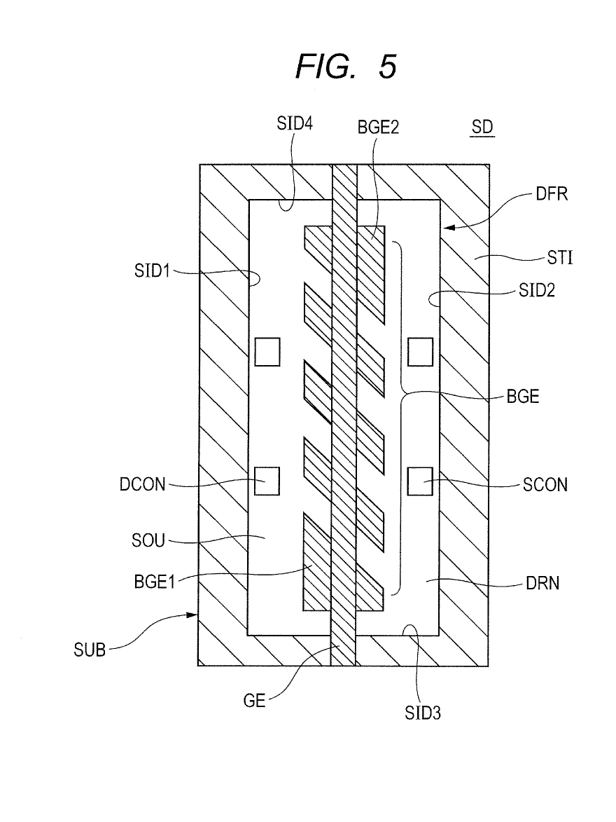

FIG. 5 is a plan view showing the structure of a semiconductor device SD according to the second embodiment. The semiconductor device SD according to the second embodiment is structurally the same as the semiconductor device SD according to the first embodiment except that the planar shape of the first buried gate electrode BGE1 and second buried gate electrode BGE2 is trapezoidal.

The second embodiment also brings about the same advantageous effects as the first embodiment. In addition, the layout design of a formerly designed planar transistor becomes usable by adjusting the lengths of the top and bottom sides of the first buried gate electrode BGE1 and second buried gate electrode BGE2.

Specifically, the circuitry of the semiconductor device includes a transistor, wiring and other elements. Therefore, if the shape of the device formation region DFR is changed, it may be necessary to change the layout for wiring and other elements. If the layout design of a formerly designed planar transistor is used, in many cases the shape of the device formation region DFR cannot be changed.

On the other hand, the interval between buried gate electrodes BGE is an important factor which determines the transistor characteristics, so it cannot be arbitrarily set. If the interval between buried gate electrodes BGE is determined so as to provide the desired transistor characteristics, the buried gate electrodes BGE may not fit in an existing device formation region DFR in which a transistor lies. In contrast, in the second embodiment, the lengths of the top and bottom sides of the first buried gate electrode BGE1 and second buried gate electrode BGE2 can be adjusted so that a plurality of buried gate electrodes BGE are arranged at desired intervals in an existing device formation region DFR in which a transistor lies.

The invention made by the present inventors has been so far explained concretely in reference to the preferred embodiments thereof. However, the invention is not limited thereto and it is obvious that these details may be modified in various ways without departing from the spirit and scope thereof.

What is claimed is:

1. A semiconductor device comprising:
a substrate including a rectangular device formation region having a first side, a second side opposite to the first side, a third side, and a fourth side;
a device separation region being formed in the substrate and surrounding the device formation region;
a plurality of buried gate electrodes being buried in the device formation region of the substrate and in a plan view, extending obliquely to the first side and being parallel to each other; and
two impurity layers being formed in the device formation region of the substrate and spaced from each other in a direction parallel to the third side and opposite to each other with the buried gate electrodes therebetween,
wherein in the buried gate electrodes, first ends opposite to the first side and second ends opposite to the second side are all parallel to the first side.

2. The semiconductor device according to claim 1,
wherein in a plan view, in a first buried gate electrode located nearest to the third side among the buried gate electrodes, a side located nearest to the third side is parallel to the third side, and
wherein in a plan view, in a second buried gate electrode located nearest to the fourth side among the buried gate electrodes, a side opposite to the fourth side is parallel to the fourth side.

3. The semiconductor device according to claim 2, wherein in a plan view, the first buried gate electrode and the second buried gate electrode are triangular.

4. The semiconductor device according to claim 2, wherein in a plan view, the first buried gate electrode and the second buried gate electrode are trapezoidal.
